(19) United States
(12) Patent Application Publication
(10) Pub. No.: US 2014/0048856 A1
(43) Pub. Date: Feb. 20, 2014

(54) SEMICONDUCTOR DEVICE INCLUDING TRANSISTORS

(71) Applicant: SAMSUNG ELECTRONICS CO., LTD., Suwon-si (KR)

(72) Inventors: JAE-JOON SONG, Daegu (KR); Se-Keun Park, Gwangmyeong-si (KR)

(73) Assignee: SAMSUNG ELECTRONICS CO., LTD., Suwon-si (KR)

(21) Appl. No.: 13/967,667

(22) Filed: Aug. 15, 2013

(30) Foreign Application Priority Data
Aug. 17, 2012 (KR) 10-2012-0090092

(51) Int. Cl. H01L 29/78

(52) U.S. Cl. CPC H01L 29/78
USPC 257/288

(57) ABSTRACT

A semiconductor device includes an active area defined by a device isolation layer and including a plurality of source/drain regions, a gate structure disposed on the active area and extending in a first direction, a stress layer contacting a side surface of each of the plurality of source/drain regions and a plurality of source/drain contacts disposed in the active area and connected to the plurality of source/drain regions.

### CROSS-REFERENCE TO RELATED APPLICATIONS

This application claims priority to Korean Patent Application No. 10-2012-0090092, filed on Aug. 17, 2012, the disclosure of which is hereby incorporated by reference herein in its entirety.

(i) Technical Field

Exemplary embodiments of the present invention relate to a semiconductor device, and more particularly, to a semiconductor device including a transistor having a stress film.

(ii) Discussion of the Related Art

In general, when a channel length of a transistor is reduced, an integration may be increased and an amount of electric current flowing through the channel may be increased. However, when the channel length is reduced to a threshold value or less, electric potentials of a source and the channel may be affected by a potential of a drain, such that, for example, a short channel effect occurs. Therefore, there may be a limitation in reducing the length of the channel to increase an operating speed of the transistor and integration.

Accordingly, research on increasing the carrier mobility of a channel to increase an output current of a transistor and increase a switching performance of the transistor have been conducted recently.

### SUMMARY

Exemplary embodiments of the present invention provide a semiconductor device including a transistor having increased carrier mobility or electron mobility.

According to an exemplary embodiment of the present invention, there is provided a semiconductor device including: an active area defined by a device isolation layer and including a plurality of source/drain regions, a gate structure disposed on the active area and extending in a first direction, a stress layer contacting a side surface of each of the plurality of source/drain regions and a plurality of source/drain contacts disposed in the active area and connected to the plurality of source/drain regions.

The gate structure may be a gate of a p-channel metal oxide semiconductor (PMOS) transistor, and the stress layer may be a compressive stress layer.

The gate structure may be a gate of an n-channel metal oxide semiconductor (NMOS) transistor, and the stress layer may be a tensile stress layer.

The stress layer may be disposed symmetrically on opposing sides of the gate structure.

The stress layer may overlap with the active area, and is formed on a partial region of the active area, which contacts a side surface of the device isolation layer.

The stress layer may be formed to extend between the plurality of source/drain contacts and toward the gate structure in a second direction that is perpendicular to the first direction.

The stress layer may overlap with the device isolation layer, and is disposed on a partial region of the device isolation layer, which contacts a side surface of the active area.

The stress layer may be formed to extend between the plurality of source/drain contacts and toward the gate structure in a second direction that is perpendicular to the first direction.

The stress layer may overlap with the active area and the device isolation layer, and may be disposed on partial regions of the active area and the device isolation layer, which contact each other.

The stress layer may be formed to extend between the plurality of source/drain contacts and toward the gate structure in a second direction that is perpendicular to the first direction.

The semiconductor device may further include a plurality of recess regions disposed under the stress layer and an insulating layer disposed on a lower surface and side surfaces of the recess regions.

The insulating layer may have a cup-shaped cross section.

According to an exemplary embodiment of the present invention, there is provided a semiconductor device including: a p-channel metal oxide semiconductor (PMOS) transistor including a plurality of source/drain regions disposed in an active area defined by a device isolation layer and a gate structure extending on the active area in a first direction, a compressive stress layer extending in the first direction and contacting a side surface of each of the source/drain regions and a plurality of source/drain contacts disposed on the active area and connected to the source/drain regions. The upper surfaces of the active area and the stress layer are located at a plane of a same level as each other.

The compressive stress layer may contact a side surface of the device isolation layer and a side surface of the active area.

The semiconductor device may further include: a plurality of recess regions disposed under the stress layer and an insulating layer disposed on a lower surface and side surfaces of the recess regions, a barrier metal layer disposed on the insulating layer and a conductive layer disposed on the barrier metal layer.
In accordance with an exemplary embodiment of the present invention, a method for manufacturing a semiconductor device is provided. The method includes forming a device isolation layer in a substrate, thereby defining an active area in the substrate, forming a well in the active area, etching an exposed portion of the active area in the substrate using a mask pattern disposed on the device isolation layer and the active area as an etching mask to thereby form a plurality of first recess regions in the active area which expose a side surface of the device isolation layer, removing the mask pattern, sequentially forming an insulating material, a barrier metal material on the device isolation layer, the first recess regions and the active area, forming a conductive material on the barrier metal material so as to fill the first recess regions, and etching the conductive material, the barrier metal material and the insulating material to form a first insulating layer, a barrier metal layer and a conductive layer on a side surface and a bottom surface of the first recess regions and a plurality second recess regions disposed above the first recess regions exposing upper surfaces of the conductive layer, the barrier metal layer and the conductive layer.
In addition, the method further includes forming a stress layer in the second recess regions which contacts the active area and the device isolation layer, sequentially forming a second insulating layer and a conductive layer on the substrate, sequentially patterning the conductive layer and the insulating layer to form a gate structure on a transistor region of the substrate, in which the gate structure includes a gate insulating layer and a gate electrode sequentially stacked on the transistor region, forming spacers covering opposing sidewalls of the gate structure, forming source/drain regions in the active area on opposing sides of the gate structure and forming a plurality of source drain contacts in the active area which are electrically connected to the source/drain regions.

### BRIEF DESCRIPTION OF THE DRAWINGS

Exemplary embodiments of the present invention will be more clearly understood from the following detailed description taken in conjunction with the accompanying drawings in which:

FIG. 1 is a cross-sectional view showing principal portions of a semiconductor device according to an embodiment of the present invention;

FIG. 2 is a cross-sectional view showing principal portions of a semiconductor device according to an embodiment of the present invention;

FIG. 3 is a cross-sectional view showing principal portions of a semiconductor device according to an embodiment of the present invention;

FIGS. 4 through 7 are layouts showing principal portions of a semiconductor device according to an embodiment of the present invention;

FIGS. 8 through 11 are layouts showing principal portions of a semiconductor device according to an embodiment of the present invention;

FIGS. 12 through 15 are layouts showing principal portions of a semiconductor device according to an embodiment of the present invention;

FIGS. 16 through 27 are cross-sectional views illustrating a method of manufacturing a semiconductor device according to a processing order, according to an embodiment of the present invention;

FIG. 28 is a circuit diagram of a complementary metal oxide semiconductor (CMOS) inverter that is an example of a semiconductor device according to an embodiment of the present invention;

FIG. 29 is a circuit diagram of a CMOS static random access memory (SRAM) device that is an example of a semiconductor device according to an embodiment of the present invention;

FIG. 30 is a circuit diagram of a CMOS NAND circuit that is an example of a semiconductor device according to an embodiment of the present invention;

FIG. 31 is a block diagram of an electronic system that is an example of a semiconductor device'according to an embodiment of the present invention;

FIG. 32 is a block diagram of an electronic system that is an example of a semiconductor device according to an embodiment of the present invention; and

FIG. 33 is a diagram of an electronic sub-system that is an example of a semiconductor device according to an embodiment of the present invention.

### DETAILED DESCRIPTION OF EXEMPLARY EMBODIMENTS

Hereinafter, exemplary embodiments of the present invention will be described more fully with reference to the accompanying drawings, in which exemplary embodiments of the inventive concept are shown. Like reference numerals in the drawings denote like elements. It will be understood that when an element such as a layer, film, region, or substrate is referred to as being “on” another element, it can be directly on the other element or intervening elements may also be present.

As used herein, the singular forms, “a”, “an”, and “the” are intended to include plural forms as well, unless the context clearly indicates otherwise.

Exemplary embodiments of the present invention may, however, be embodied in many different forms and should not be construed as limited to exemplary embodiments set forth herein.

As used herein, the term “and/or” includes any and all combinations of one or more of the associated listed items.

As used herein, the term “and/or” includes any and all combinations of one or more of the associated listed items.

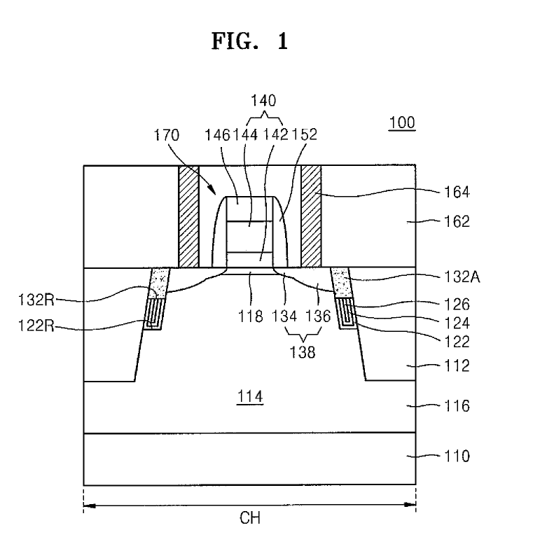

FIG. 1 is a cross-sectional view showing principal portions of a semiconductor device 100 according to an embodiment of the present invention.

Referring to FIG. 1, the semiconductor device 100 includes, for example, a substrate 110 and a plurality of stress films 132A. The substrate 110 may be a rigid substrate such as, for example, a silicon substrate, a silicon on insulator (SOI) substrate, a gallium-arsenic substrate, a silicon germanium substrate, a ceramic substrate, a quartz substrate, a glass substrate for displays, or a flexible plastic substrate formed of, for example, polyimide, polyethylene terephthalate (PET), polyethylene naphthalate (PEN), poly methyl methacrylate (PMMA), polycarbonate (PC), polyether sulfone (PES), or polyester.

The substrate 110 may configure one of selected from, for example, a system large scale integration (LSI), a logic circuit, an image sensor such as a complementary metal oxide semiconductor (CMOS) imaging sensor (CIS), a memory device such as a flash memory, a dynamic random access memory (DRAM), a static random access memory (SRAM), an electrically erasable programmable read-only memory (EEPROM), a parameter RAM (PRAM), a magnetoresistive RAM (MRAM), or a resistive RAM (RRAM), or a micro-electro-mechanical system (MEMS).

A well 116 is formed on the substrate 110, and a transistor 170 is formed on the well 116. For example, in an embodiment, the well 116 may be an N-type well, and the transistor 170 may be a PMOS transistor. Alternatively, for example, in an embodiment, the well 116 may be a P-type well, and the transistor 170 may be an NMOS transistor.

An active area 114 is defined by a device isolation layer 112 on the substrate 110. The device isolation layer 112 may be, for example, a shallow trench isolation (STI).

The transistor 170 formed on the active area 114 of the substrate 110 includes, for example, a gate structure 140 in which a gate electrode layer 142 and a gate electrode 144 are sequentially stacked. The gate structure 140 extends, for example, in a direction as crossing throughout the active area 114.

In addition, a capping layer 146 is formed on the gate electrode 144.

Alternatively, in an embodiment, the capping layer 146 may, for example, be omitted. Here, the capping layer 146 may be formed of, for example, a silicon nitride material but, exemplary embodiments of the present invention are not limited thereto.

For example, the gate insulating layer 142 may be formed of silicon oxide (SiO₂), silicon oxynitride (SiON), silicon nitride (Si₃N₄), germanium oxynitride (GexOyNz), germanium silicon oxide (GexSiyOz), a high K material, and a combination thereof. In addition, the gate insulating layer 142 may be formed as a stacked layer in which the above materials are stacked sequentially. The high-K material may be, for example, hafnium oxide (HfO₂), zirconium oxide (ZrO₂), aluminum oxide (Al₂O₃), tantalum pentoxide (Ta₂O₅), hafnium silicon oxynitride (HfSiON), hafnium silicate (HfSixOy), zirconium silicate (ZrSiO₄), or a combined layer thereof.

In addition, the gate electrode 144 may be formed of, for example, polysilicon (poly-Si), polysilicon germanium (poly-SiGe), dopped poly-Si, metal such as tantalum (Ta), tantalum nitride (TaN), tantalum silicon nitride (TaSiN), titanium nitride (TiN), molybdenum (Mo), ruthenium (Ru), nickel (Ni), nickel silicide (NiSi), or a stacked layer in which the above materials are sequentially stacked.

Opposite side walls of the gate structure 140 are covered by spacers 152. The spacers 152 may be formed of, for example, a silicon oxide film or a silicon nitride film but exemplary embodiments of the present invention are not limited thereto.

The transistor 170 includes, for example, source/drain regions 138 formed on the substrate 110 at opposite sides of the gate structure 140. The source/drain regions 138 respectively include, for example, extended source/drain regions 134 arranged under the gate structure 140 and in the active area 114, and deep source/drain regions 136 formed in the active area 114 aligned by the gate structure 140 and the spacers 152.

For example, in the active area 114 of the substrate 110 located between the pair of source/drain regions 138, a channel region 118 is formed adjacent to the gate insulating layer 142.

Also, source/drain contacts 164 formed at opposite side surfaces of the transistor 170 are formed, for example, in an interlayer dielectric 162 on the active area 114 to contact the source/drain regions 138.

First recess regions 132R are formed, for example, in a predetermined region of the active area 114, which contacts the device isolation layer 112, and the stress layers 132A are filled in the first recess regions 132R. The first recess region 132R may be formed to be, for example, symmetrical with each other based on the transistor 170. Also, the stress layers 132A contact, for example, one side surface of the source/drain regions 138.

For example, the stress layer 132 may overlap with the active area 114, and may be formed on a partial region of the active area 114, which contacts a side surface of the device isolation layer 112.

The stress layer 132A may be, for example, a nitride layer formed of silicon nitride (SiN), or an oxide layer formed of SiO₂. For example, when the stress layer 132A is formed of SiN, a silane (SiH₄) gas is supplied in an amount of about 10 to about 100 sccm, an ammonia (NH₃) gas is supplied in an amount of about 10 to about 100 sccm, and an N₂ gas is supplied in an amount of about 1 to about 5 slur by using a plasma enhanced chemical vapor deposition (PECVD) method. Also, a radio frequency (RF) power of, for example, about 50 to about 1000 W is applied, and a processing temperature may be, for example, about 400 to about 500° C. In particular, it is determined whether the SiN layer has a tensile stress or a compressive stress, according to a ratio of N—H bonding and Si—H bonding in the SiN layer. That is, if a ratio of N—H bonding/Si—H bonding is about 1 to about 5, the SiN layer has the tensile stress, and if the ratio of the N—H bonding/Si—H bonding is about 5 to about 20, the SiN layer has the compressive stress. Therefore, in the present embodiment in which the compressive stress layer 132A is formed, the ratio of the N—H bonding/Si—H bonding is adjusted to, for example, about 5 to about 20 in the SiN layer.

Alternatively, in an embodiment, if the stress layer 132A is a tensile stress layer, the stress layer 132A may be formed of, for example, a nitride layer of SiN by using, for example, a low pressure chemical vapor deposition (LPCVD) method.

That is, the stress layer 132A may be formed as the tensile stress layer or the compressive stress layer by adjusting the deposition conditions such as the pressure and the temperature.

The transistor 170 is, for example, a p-type transistor, and the stress layer 132A is the compressive stress layer. Thus, an effective mass in the channel region 118 is increased and a hole mobility is also increased, and accordingly, an on-current characteristic of the PMOS transistor 170 may be increased.

On the other hand, if the transistor 170 is, for example, an n-type transistor and the stress layer 132A is a tensile stress layer, the tensile stress is applied to the channel region so as to increase an electron mobility. Accordingly, an operating performance of the transistor 170 may be increased.

Also, as the stress layer 132A is an insulating layer formed on the first recess region 132R of the active area 114, a range of the active area 114 may vary depending on a location of the first recess region 132R.

In addition, a second recess region 122R may be further formed, for example, under the first recess region 132R in the active region 114 contacting the device isolation layer 112. An insulating layer 122 having, for example, a cup-shaped cross section may be formed on a lower surface and side surfaces of the second recess region 122R. The insulating layer 122 may be an oxide layer formed of, for example, SiO₂ but exemplary embodiments of the present invention are not limited thereto.

Also, for example, a barrier metal layer 124 and a conductive layer 126 may be further formed on the insulating layer 122.

The barrier metal layer 124 may have, for example, a cup-shaped cross section like the insulating layer 122. Also, the barrier metal layer 124 may include, for example, one selected from tungsten nitride (WN), tantalum nitride (TaN), and titanium nitride (TiN).

The conductive layer 126 may be formed of, for example, a conductive polysilicon, a metal, a metal silicide, a conductive metal nitride, a conductive metal oxide, or an alloy thereof. For example, the conductive layer 126 may be formed of polysilicon doped with impurities, tungsten (W), tungsten nitride (W₂N, WN, WN₂) tungsten silicide (WSi₂) , aluminum (Al), aluminum nitride (AlN), tantalum (Ta), tantalum nitride (TaN), tantalum silicide (TaSi₂), titanium (Ti), titanium nitride (TiN), cobalt silicide (CoSi₂), molybdenum (Mo), ruthenium (Ru), nickel (Ni), nickel silicide (Nisi), or a combination thereof.

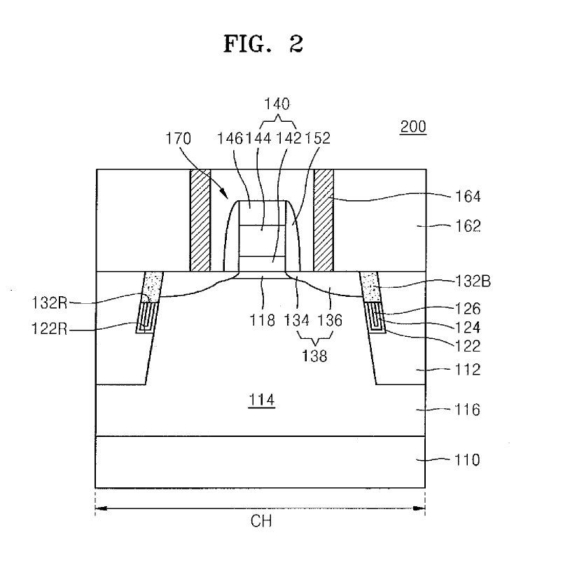

FIG. 2 is a cross-sectional view showing principal parts of a semiconductor device 200 according to an embodiment of the present invention. In FIG. 2, the same reference numerals as those of FIG. 1 denote the same elements, and detailed descriptions thereof are not provided here.

Referring to FIG. 2, the semiconductor substrate 200 includes the substrate 110 that may have the same configuration as that of the substrate 110 shown in FIG. 1.

The active area 114 on the substrate 110 is defined by the device isolation layer 112. In addition, the first recess region 132R is formed, for example, on a predetermined region in the device isolation layer 112, which contacts the active area 114, and a stress layer 132B fills in the first recess region 132R. The first recess region 132R may be formed, for example, symmetrically based on the transistor 170.

For example, the stress layer 132B may overlap with the device isolation layer 112, and may be formed on a partial region of the device isolation layer 112, which contacts a side surface of the active area 114.

Also, the stress layer 132B has a compressive stress, and may be formed of a nitride layer such as, for example, a SiN or an oxide layer such as a SiO₂. The stress layer 132B may be formed as the compressive stress layer by adjusting, appropriately deposition conditions such as a pressure and a temperature.

Also, the semiconductor device 200 may further include, for example, a second recess region 122R formed under the first recess region 132R in the device isolation layer 112 contacting the active area 114. The insulating layer 122 having, for example, a cup-shaped cross section may be formed on a lower surface and side surfaces of the second recess region 122R. The insulating layer 122 may be, for example, an oxide layer formed of SiO₂ but exemplary embodiments of the present invention are not limited thereto.

In addition, the semiconductor device 200 may further include, for example, a barrier metal layer 124 and a conductive layer 126 formed on the insulating layer 122.

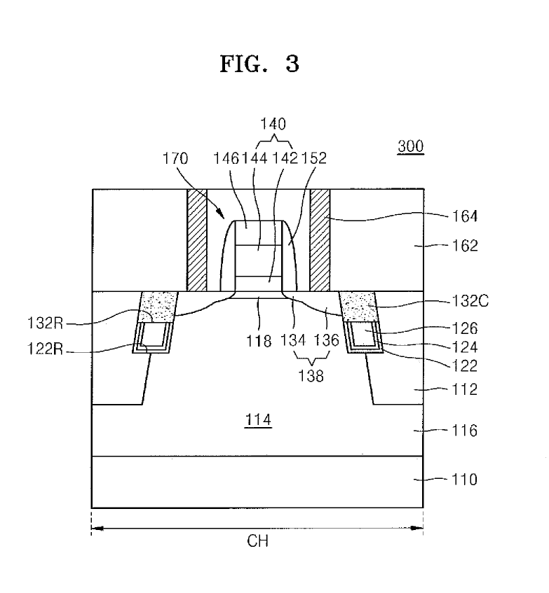

FIG. 3 is a cross-sectional view showing principal portions of a semiconductor device 300 according to an embodiment of the present invention. In FIG. 3, the same reference numerals as those of FIG. 1 denote the same elements, and detailed descriptions thereof are not provided here.

Referring to FIG. 3, the semiconductor substrate 300 includes the substrate 110 that may have the same configuration as that of the substrate 110 shown in FIG. 1.

The active area 114 on the substrate 110 is defined by the device isolation layer 112. In addition, the first recess region 132R is formed, for example, on a predetermined region where the active area 114 and the device isolation layer 112 contact each other. That is, the first recess region 132R is formed by, for example, recessing some parts of the device isolation layer 112 and the active area 114 simultaneously, in the region where the device isolation layer 112 and the active area 114 contact each other. The first recess region 132R may be formed, for example, symmetrically based on the transistor 170.

Also, a stress layer 132C fills in the first recess region 132R. For example, the stress layer 132C overlaps with the active area 114 and the device isolation layer 112, and may be formed on partial regions of the active area 114 and the device isolation layer 112, which contact each other.

For example, the stress layer 132C has a compressive stress, and may be formed as a nitride layer formed of SiN or an oxide layer formed of SiO₂. The stress layer 132C may be formed as the compressive stress layer by adjusting appropriately deposition conditions such as a pressure and a temperature.

Also, the semiconductor device 300 may further include, for example, a second recess region 122R formed under the first recess region 132R in the region where the active area 114 and the device isolation layer 112 contact each other. The insulating layer 122 having, for example, a cup-shaped cross section may be formed on a lower surface and side surfaces of the second recess region 122R. The insulating layer 122 may be, for example, an oxide layer formed of SiO₂ but exemplary embodiments of the present invention are not limited thereto.

In addition, the semiconductor device 300 may further include, for example, a barrier metal layer 124 and a conductive layer 126 formed on the insulating layer 122.

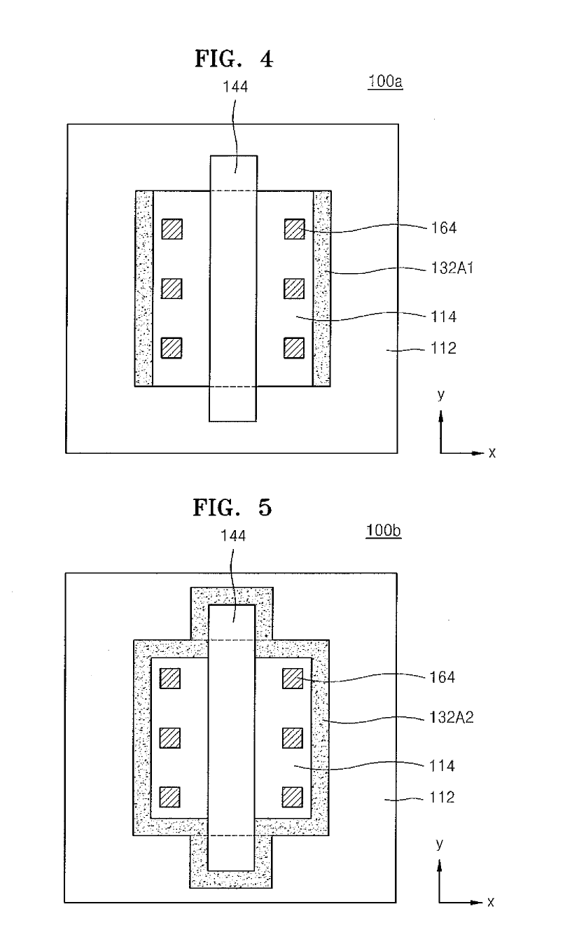

FIGS. 4 through 7 are layouts showing principal configurations of semiconductor devices 100a, 100b, 100c, and 100d according to an embodiment of the present invention. In FIGS. 4 through 7, the same reference numerals as those of FIG. 1 denote the same elements, and detailed descriptions thereof are not provided here. In addition, stress layers 132A1, 132A2, 132A3, and 132A4 shown in FIGS. 4 through 7 are the same as the stress layer 132A of FIG. 1.

Referring to FIG. 4 and FIG. 1 together, the active area 114 is defined by the device isolation layer 112, and the stress layer 132A1 is formed, for example, on a partial region of the active area 114, which overlaps with the active area 114 based on a gate electrode 144 and contacts a side surface of the device isolation layer 112, in a Y-axis direction.

That is, the stress layer 132A1 is spaced apart a predetermined distance from source/drain contacts 164 that are formed at opposite sides based on the gate electrode 144, in the Y-axis direction.

Referring to FIG. 5 and FIG. 1 together, the active area 114 is defined by the device isolation layer 112. The stress layer 132A2 that overlaps with the active area 114 is formed, for example, on a partial region of the active area 114, which contacts the side surface of the device isolation layer 112, while surrounding edges of the active area 114 in the Y-axis direction.

That is, the stress layer 132A2 is formed to, for example, surround the edges of the active area 114, and thus, may be formed as a closed loop, unlike the stress layer 132A1 that is divided by the gate electrode 144 as shown in FIG. 4.

Also, unlike the stress layer 132A1 in the example of FIG. 4, the stress layer 132A2 in the present exemplary embodiment that surrounds the active area 114 may vary according to the shape of the active area 114.

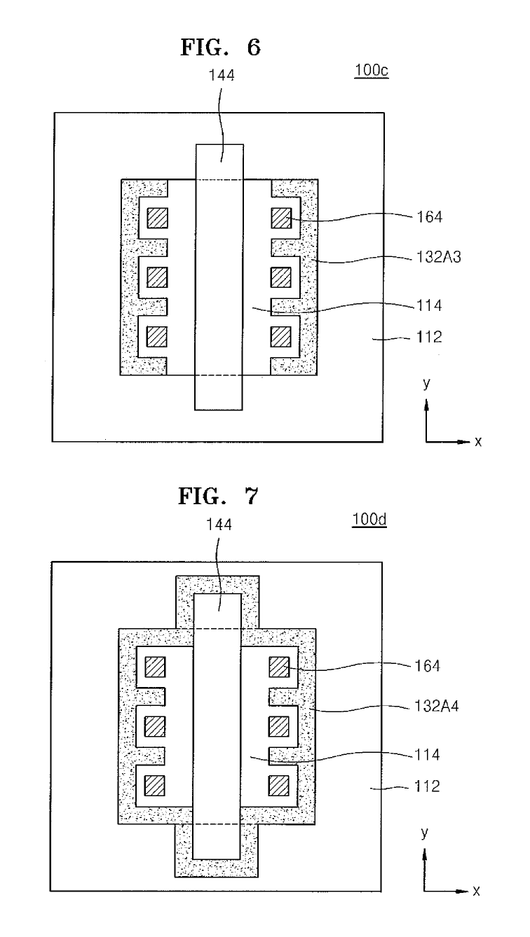

Referring to FIG. 6 and FIG. 1 together, the stress layer 132A3 that is divided based on the gate electrode 144 is formed.

The stress layer 132A3, for example, overlaps with the active area 114, and is formed on a partial region of the active area 114, which contacts the side surface of the device isolation layer 112, in the Y-axis direction. Also, the stress layer 132A3 may also extend, for example, in an X-axis direction that is perpendicular to the Y-axis direction toward the gate electrode 144, between the plurality of source/drain contacts 164.

That is, the stress layer 132A3 shown in FIG. 6 extends, for example, to a predetermined length between the plurality of source/drain contacts 164 from the shape of the stress layer 132A1 shown in FIG. 4, such that the stress layer 132A3 may be formed as a pair of combs facing each other.

Also, in FIG. 6, the stress layer 132A3 is formed, for example, as a straight line but exemplary embodiments of the present invention are not limited thereto. For example, the stress layer 132A3 may be formed as a curve according to processing conditions.

Referring to FIG. 7 and FIG. 1 together, the stress layer 132A4, for example, overlaps with the active area 114, and extends to a predetermined length between the plurality of source/drain contacts 164 while surrounding edges of the active area 114 on a partial region of the active area 114, which contacts the side surface of the device isolation layer 112.

That is, the stress layer 132A4 is formed, for example, surrounding the edges of the active area 114, and may be formed as a single closed loop shape, unlike the stress layer 132A3 that is divided into pieces as shown in FIG. 6.

Also, unlike the stress layer 132A3 shown in FIG. 6, the shape of the stress layer 132A4 in the present exemplary embodiment surrounding the active area 114 may vary according to the shape of the active area 114.

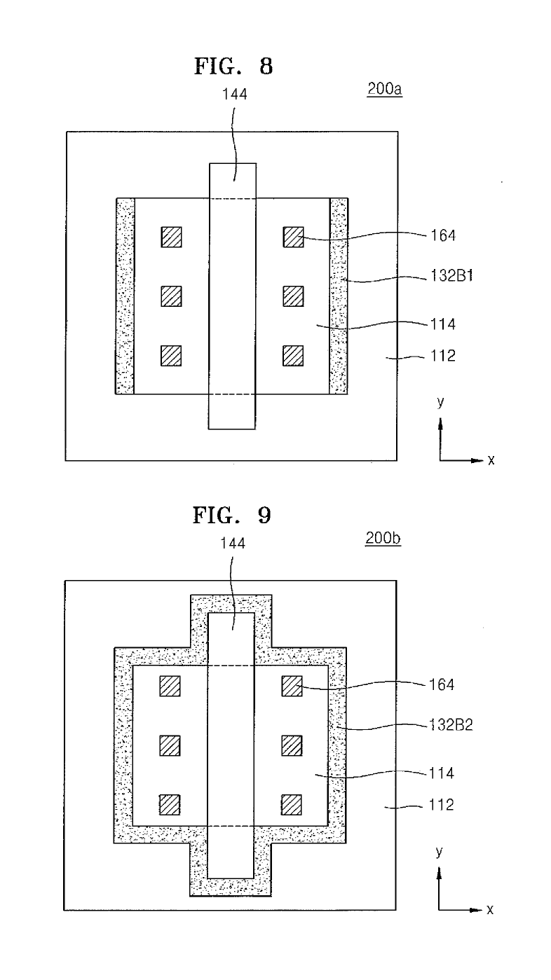

FIGS. 8 through 11 are layouts showing principal configurations of semiconductor devices 200a, 200b, 200c, and 200d according to an embodiment of the present invention. In FIGS. 8 through 11, like reference numerals as those of FIG. 2 denote like elements, and thus, detailed descriptions thereof are not provided here. In addition, stress layers 132B1, 132B2, 132B3, and 132B4 shown in FIGS. 8 through 11 are the same as the stress layer 132B of FIG. 2.

Referring to FIG. 8 and FIG. 2 together, the active area 114 is defined by the device isolation layer 112. The stress layer 132131, for example, overlaps with the device isolation layer 112, and is formed on a partial region of the device isolation layer 112, which contacts the side surface of the active area 114, in the Y-axis direction.

That is, the stress layer 132B1 is formed, for example, to be spaced apart predetermined distances from the source/drain contacts 164 formed at opposite sides based on the gate electrode 144.

Referring to FIG. 9 and FIG. 2 together, the stress layer 132B2, for example, overlaps with the device isolation layer 112, and is formed on a partial region of the device isolation layer 112, which contacts the side surface of the active area 114, in the Y-axis direction while surrounding edges of the active area 114.

That is, the stress layer 132B2 is formed, for example, on the partial region of the device isolation layer 112 while surrounding the edges of the active area 114, and may be formed as a single closed loop unlike the stress layer 132B1 that is divided based on the gate electrode 144 shown in FIG. 8. The stress layer 132B2 also surrounds the gate electrode 144, as well as the active area 114.

Also, the stress layer 132B2 formed on the device isolation layer 112 may vary according to the shape of the active area 114.

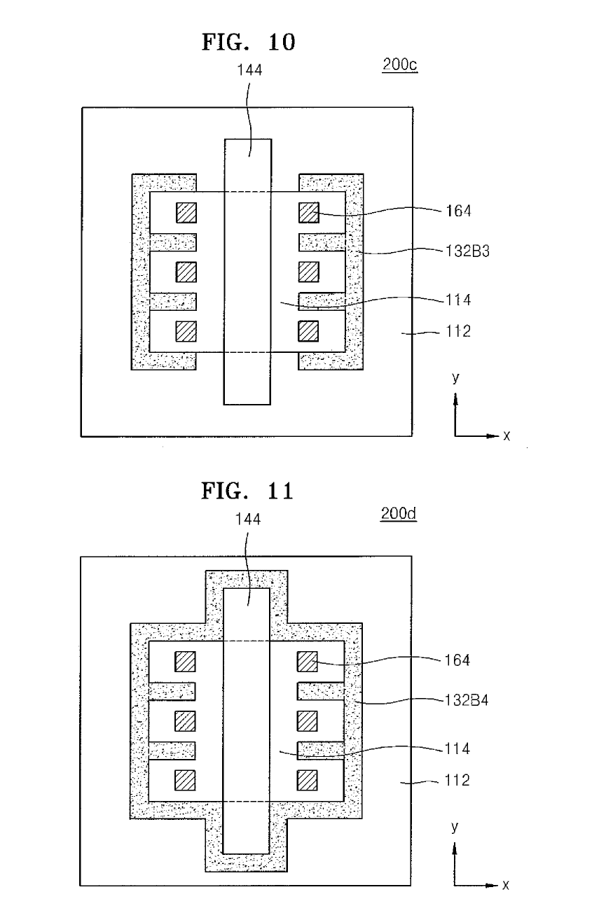

Referring to FIG. 10 and FIG. 2 together, the stress layer 132B3 that is, for example, divided into two parts based on the gate electrode 144 is formed. The stress layer 132B3, for example, overlaps with the device isolation layer 112, and is formed on a partial region of the device isolation layer 112, which contacts the side surface of the active area 114, in the Y-axis direction. Also, the stress layer 132B3 extends, for example, in the X-axis direction that is perpendicular to the Y-axis direction toward the gate electrode 144, between the plurality of source/drain contacts 164.

That is, the stress layer 132B3 shown in FIG. 10 is formed by, for example, extending the stress layer 132B1 shown in FIG. 8 to a predetermined length between the plurality of source/drain contacts 164, and the stress layer 132B3 is divided into two parts based on the gate electrode 144 to be formed as a pair of combs facing each other.

In addition, the stress layer 132B3 is formed as, for example, a straight line in FIG. 10 but exemplary embodiments of the present invention are not limited thereto. Rather, the stress layer 132B3 may be formed in various shapes according to processing conditions.

Referring to FIG. 11 and FIG. 2 together, the stress layer 132B4, for example, overlaps with the device isolation layer 112, and extends to a predetermined length between the plurality of source/drain contacts 164 while surrounding edges of the active area 114 on a partial region of the device isolation layer 112, which contacts the side surface of the active area 114.

That is, the stress layer 132B4 is formed, for example, surrounding the edges of the active area 114, and may be formed as a single closed loop shape, unlike the stress layer 132B3 that is divided into pieces as shown in FIG. 10.

Also, unlike the stress layer 132B3 shown in FIG. 10, the shape of the stress layer 132B4 in the present exemplary embodiment surrounding the active area 114 may vary according to the shape of the active area 114.

FIGS. 12 through 15 are layouts of principal configurations of semiconductor devices 300a, 300b, 300c, and 300d according to an embodiment of the present invention. In FIGS. 12 through 15, like reference numerals as those of FIG. 3 denote like elements, and thus, detailed descriptions thereof are not provided here. In addition, stress layers 132C1, 132C2, 132C3, and 132C4 shown in FIGS. 12 through 15 are the same as the stress layer 132C of FIG. 3.

Referring to FIG. 12 and FIG. 3 together, the active area 114 is defined by the device isolation layer 112. The stress layer 132C1, for example, overlaps with the active area 114 and the device isolation layer 112 based on the gate electrode 144, and is formed on partial regions of the active area 114 and the device isolation layer 112, which contact each other, in the Y-axis direction.

That is, the stress layer 132C1 is formed, for example, to be spaced apart predetermined distances from the source/drain contacts 164 formed at opposite sides based on the gate electrode 144.

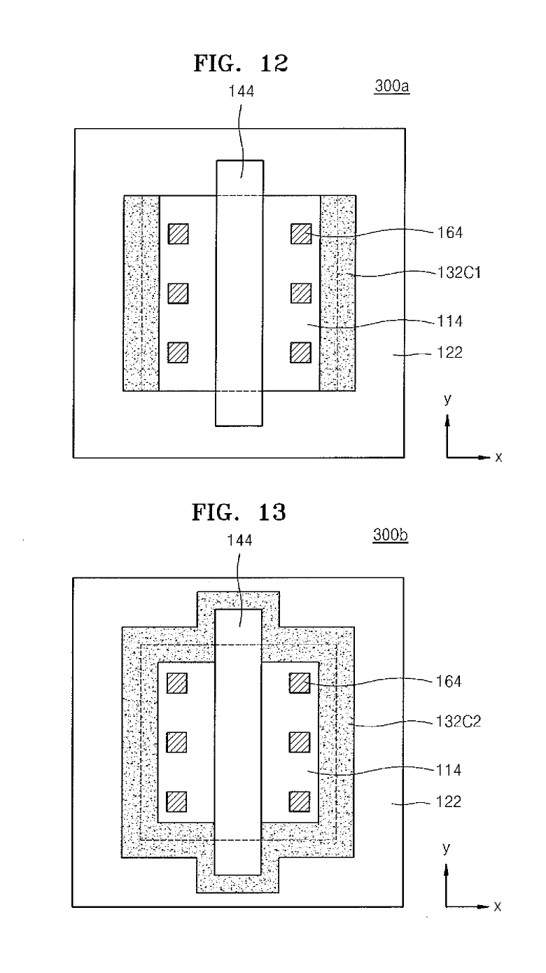

Referring to FIG. 13 and FIG. 3 together, the stress layer 132C2, for example, overlaps with the active area 114 and the device isolation layer 112, and is formed on partial regions of the active area 114 and the device isolation layer 112, which contact each other, in the Y-axis direction while surrounding edges of the active area 114.

That is, the stress layer 132C2 is formed, for example, surrounding the edges of the active area 114, and may be formed as a single closed loop unlike the stress layer 132C1 that is divided based on the gate electrode 144 shown in FIG. 12.

In addition, the stress layer 132C2 surrounding the active area 114 may vary according to the shape of the active area 114.

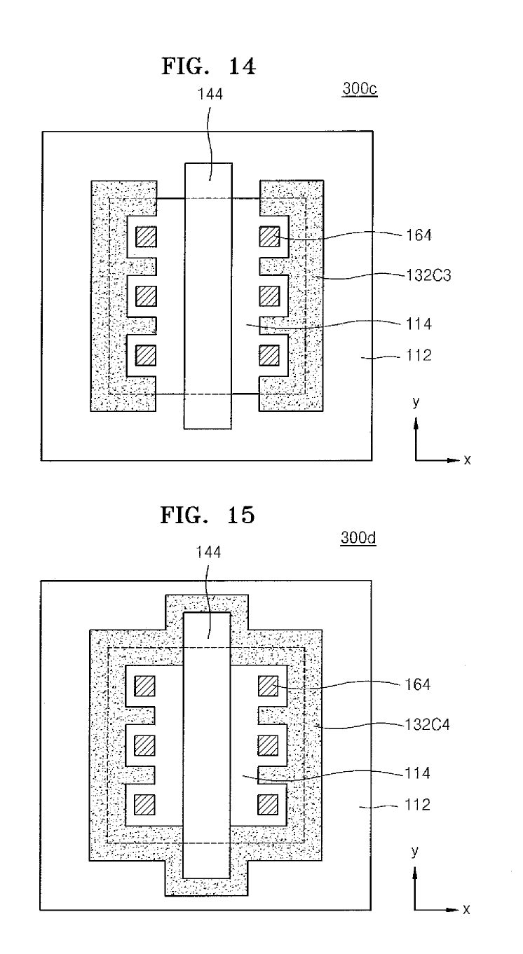

Referring to FIG. 14 and FIG. 3 together, the stress layer 132C3 that is, for example, divided into two parts based on the gate electrode 144 is formed.

The stress layer 132C3, for example, overlaps with the active area 114 and the device isolation layer 112, and is formed on partial regions of the active area 114 and the device isolation layer 112, which contact each other, in the Y-axis direction. In addition, the stress layer 132C3 extends, for example, in the X-axis direction that is perpendicular to the Y-axis direction toward the gate electrode 144, between the plurality of source/drain contacts 164.

That is, the stress layer 132C3 is formed by, for example, extending the stress layer 132C1 shown in FIG. 12 to a predetermined length between the plurality of source/drain contacts 164, and the stress layer 132C3 is divided, for example, into two parts based on the gate electrode 144 and formed as a pair of combs facing each other.

Also, the stress layer 132C3 is formed as, for example, a straight line in FIG. 14; but exemplary embodiments of the present invention are not limited thereto. Rather, the stress layer 132C3 may be formed as, for example, a curve according to processing conditions.

Referring to FIG. 15 and FIG. 3 together, the stress layer 132C4, for example, overlaps with the active area 114 and the device isolation layer 112, and extends to a predetermined length between the plurality of source/drain contacts 164 while surrounding edges of the active area 114 on partial regions of the active area 114 and the device isolation layer 112, which contact each other.

That is, the stress layer 132C4 is formed, for example, surrounding the edges of the active area 114, and may be formed as a single closed loop shape, unlike the stress layer 132C3 that is divided into pieces as shown in FIG. 14.

Also, unlike the stress layer 132C3 shown in FIG. 14, the shape of the stress layer 132C4 in the present exemplary embodiment surrounding the active area 114 may vary according to the shape of the active area 114.

FIGS. 16 through 27 are cross-sectional views illustrating a method of manufacturing the semiconductor device 100 (refer to FIG. 1) according to a processing order, according to an embodiment of the present invention. In FIGS. 16 through 27, reference numerals that are the same as those of FIG. 1 denote the same elements, and thus, detailed descriptions thereof are not provided here.

Referring to FIG. 16, the device isolation layer 112 is formed on the substrate 110 to define the active area 114.

The device isolation layer 112 may be formed of, for example, an oxide layer, a nitride layer, or a combination thereof.

A plurality of wells 116 of, for example, a second type in which impurity ions of a second type are injected are formed in the active area 114.

For example, in an embodiment of the present invention, a transistor region (CH) may be a PMOS transistor region, and the well 116 may be an N-type well. Alternatively, in an embodiment, the transistor region CH may be, for example, an NMOS transistor region, and the well 116 may be, for example, a P-type well.

For example, the transistor region CH may configure a device selected among an image sensor such as a system LSI, a logic circuit, and a CIS, a memory device such as a flash memory, a DRAM, an SRAM, an EEPROM, a PRAM, an MRAM, or a RRAM, and a micro-electro-mechanical system (MEMS).

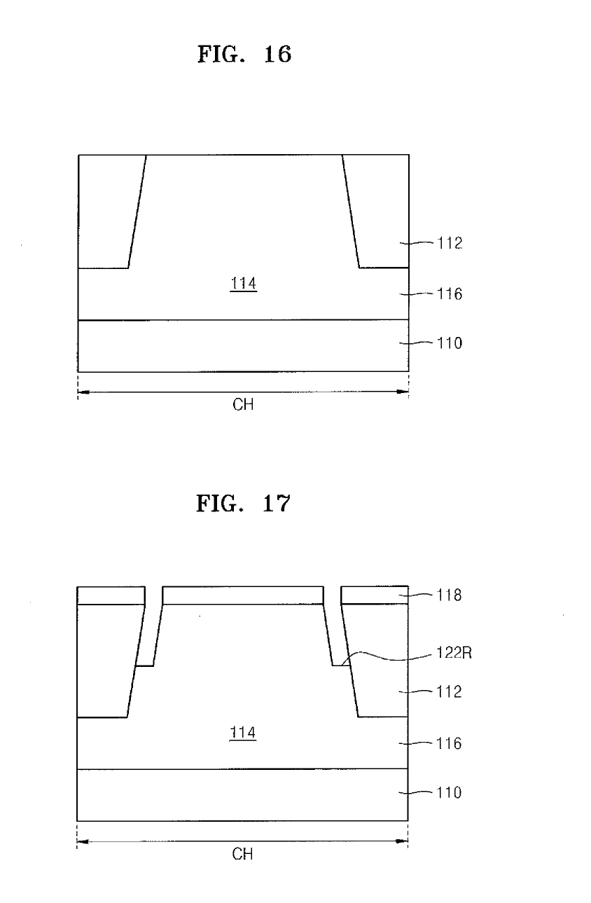

Referring to FIG. 17, the exposed active area 114 on the substrate 110 is etched by, for example, using a mask pattern 118 formed on the device isolation layer 112 and the active area 114 as an etching mask, so that a plurality of second recess regions 122R are formed in the active area 114.

The second recess regions 122R may be formed, for example, in predetermined regions of the active area 114 so as to expose a side surface of the device isolation layer 112. However, exemplary embodiments of the present invention are not limited thereto, but rather the second recess regions 122R may be formed, for example, in the active area 114 to be spaced apart from the device isolation layer 112.

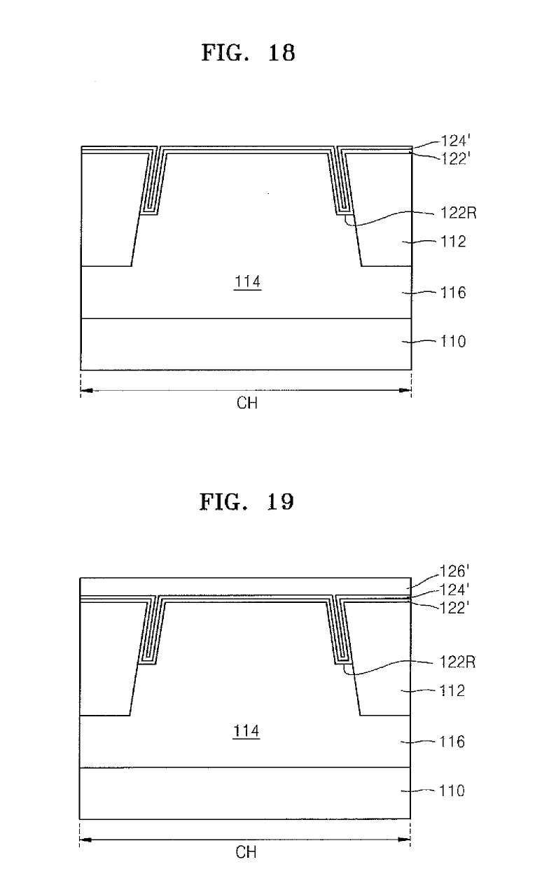

For example, referring to FIG. 18, after removing the mask pattern 118, an insulating material 122′ and a barrier metal material 124′ are sequentially fanned on the device isolation layer 112, the second recess regions 122R, and the active area 114.

In the present embodiment of the present invention, the insulating material 122′ may be, for example, an oxide material or a metal oxide material. For example, the insulating material 122′ may be, for example, at least one selected from a silicon oxide material, a silicon oxynitride material, a hafnium oxide material, a zirconium oxide material, an aluminum oxide material, and a tantalum oxide material.

In the present embodiment of the present inventive concept, the insulating material 122′ may be formed by, for example, using a chemical vapor deposition (CVD) method, an atomic layer deposition (ALD) method, or a thermal oxidation method.

In the present embodiment of the present inventive concept, the barrier metal material 124′ may be, for example, one selected from a tungsten nitride material (WN), TaN, and TiN.

Referring to FIG. 19, a conductive material 126′ is formed on the barrier metal material 124′ so as to fill the second recess regions 122R.

The conductive material 126′ may be formed of, for example, a conductive polysilicon, a metal, a metal silicide, a conductive metal nitride, a conductive metal oxide, or an alloy thereof. For example, the conductive material 126′ may be formed of polysilicon doped with impurities, W, WN, tungsten silicide, Al, aluminum nitride, Ta, TaN, tantalum silicide, Ti, TiN, cobalt silicide, Mo, Ru, Ni, NiSi, or a combination thereof.

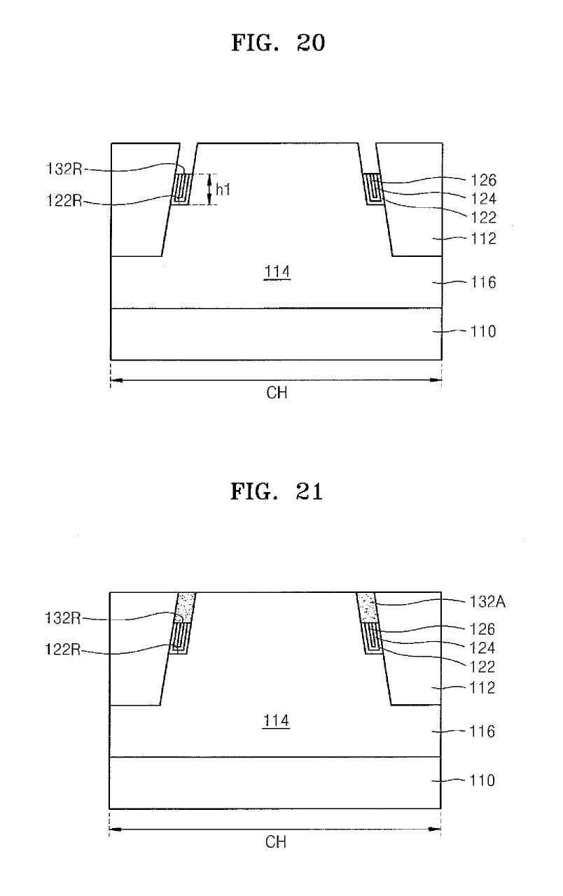

Referring to FIG. 20, the conductive material 126′, the barrier metal material 124′, and the insulating material 122′ are, for example, etched to form first recess regions 132R for forming a stress layer 132A (refer to FIG. 21). In addition, an insulating layer 122 of a predetermined height h1 having, for example, a cup-shaped cross section, a barrier metal layer 124, and a conductive layer 126 filling the barrier metal layer 124 are formed in each of the second recess regions 122R.

Upper surfaces of the insulating layer 122, the barrier metal layer 124, and the conductive layer 126 may be located, for example, at a plane of the same level.

For example, referring to FIG. 21, a stress material (not shown) covers the first recess regions 132R, and then, a planarization process is performed until upper surfaces of the device isolation layer 112 and the active area 114 are exposed so as to form the stress layer 132A.

The stress layer 132A is formed, for example, in the active area 114 contacting the device isolation layer 112, and an upper surface of the stress layer 132A may be located at the same level as that of the upper surfaces of the device isolation layer 112 and the active area 114.

The stress layer 132A may be formed of, for example, a nitride layer such as SiN or an oxide layer such as SiO₂. For example, if the stress layer 132A is formed of SiN, a Sin₄ gas is supplied in an amount of about 10 to about 100 sccm, an NH₃ gas is supplied in an amount of about 10 to about 100 sccm, and an N₂ gas is supplied in an amount of about 1 to about 5 slm by using a plasma enhanced chemical vapor deposition (PECVD) method. Also, a radio frequency (RF) power of, for example, about 50 to about 1000 W is applied, and a processing temperature may be, for example, about 400 to about 500° C.

In particular, it is determined whether the SiN layer has a tensile stress or a compressive stress, according to a ratio of N—H bonding and Si—H bonding in the SiN layer. That is, if a ratio of N—H bonding/Si—H bonding is about 1 to about 5, the SiN layer has the tensile stress, and if the ratio of the N—H bonding/Si—H bonding is about 5 to about 20, the SiN layer has the compressive stress. Therefore, in the present embodiment in which the compressive stress layer 132A is formed, the ratio of the N—H bonding/Si—H bonding is adjusted to, for example, about 5 to about 20 in the SiN layer.

Alternatively, in an embodiment, if, for example, the transistor region CH is an NMOS transistor region and the well 116 is the p-type well, the stress layer 132A may be a tensile stress layer. For example, when the stress layer 132A is the tensile stress layer, the stress layer 132A may be formed of a nitride layer of SiN by using a low pressure chemical vapor deposition (LPCVD) method. That is, the stress layer 132A may be formed as the tensile stress layer or the compressive stress layer by adjusting the deposition conditions such as the pressure and the temperature.

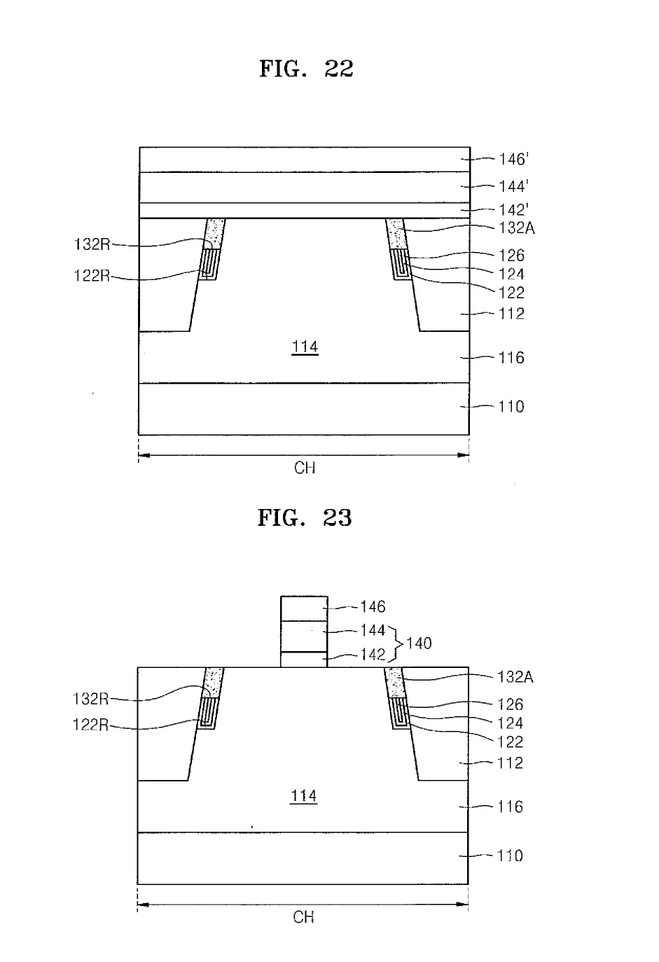

Referring to FIG. 22, an insulating layer 142′, a conductive layer 144′, and a preliminary capping layer 146′ are, for example, sequentially formed on the substrate 110.

In the present embodiment of the present invention, the insulating layer 142′ is formed of, for example, an oxide material or a metal oxide material. For example, the insulating layer 142′ may be formed of, for example, at least one selected from silicon oxide, silicon oxynitride, hafnium oxide, zirconium oxide, aluminum oxide, and tantalum oxide. In the present embodiment of the present invention, the insulating layer 142′ is formed by, for example, using a CVD, an ALD, or a thermal oxidation method.

In the present embodiment of the present invention, the conductive layer 144′ may be formed of a conductive polysilicon, a metal silicide, a conductive metal nitride, a conductive metal oxide, or an alloy thereof. For example, the conductive layer 144′ may be formed of polysilicon doped with impurities, tungsten (W), tungsten nitride, tungsten silicide, aluminum (Al), aluminum nitride, tantalum (Ta), TaN, tantalum silicide, titanium (Ti), TiN, cobalt silicide, molybdenum (Mo), ruthenium (Ru), nickel (Ni), NiSi, or a combination thereof. In the present embodiment of the present invention, the conductive layer 144′ is formed by using, for example, the CVD, the ALD, or a sputtering method.

The preliminary capping layer 146′ may be formed of, for example, silicon nitride.

Referring to FIG. 23, the preliminary capping layer 146′, the conductive layer 144′, and the insulating layer 142′ are, for example, patterned sequentially to form the gate structure 140 on the transistor region CH.

The gate structure 140 includes, for example, a gate insulating layer 142 and a gate electrode 144 located on the transistor region CH. In addition, a capping layer 146 may be selectively formed on the gate electrode 144.

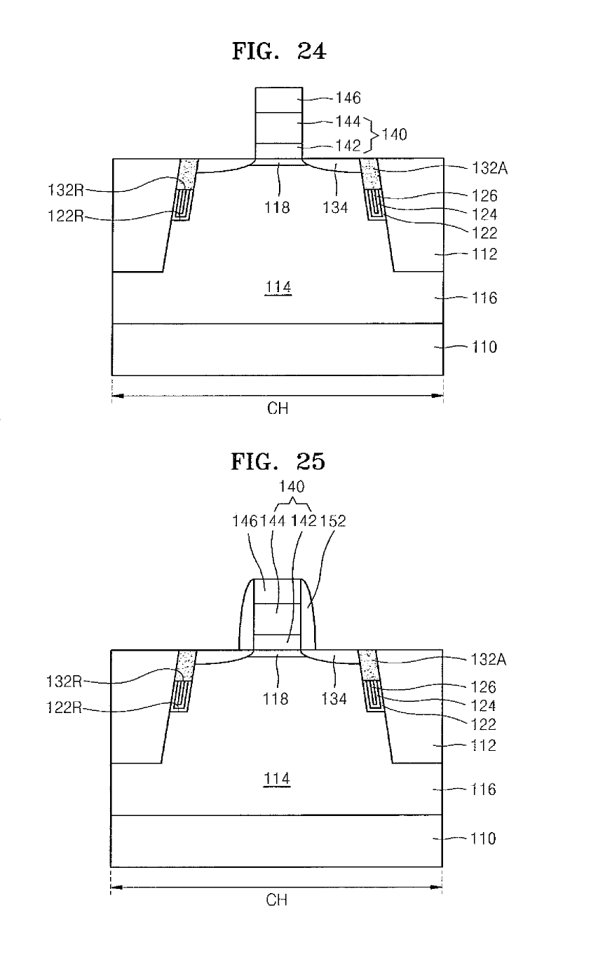

Referring to FIG. 24, low concentration impurity regions 134 are, for example, formed in the active area 114. The low concentration impurity regions 134 correspond to extended source/drain regions 134 formed in the active area 114. In addition, the low concentration impurity regions 134 may be, for example, p-type. For example, P-type impurities, such as boron (B) is injected by using the gate structure 140 of the PMOS transistor as an ion injection mask to form the p-type low concentration impurity regions 134 in the active area 114. A region between the p-type low concentration impurity regions 134 is, for example, a channel region 118 of the PMOS transistor 170.

Referring to FIG. 25, spacers 152 covering opposite side walls of the gate structure 140 are formed.

The spacers 152 may be formed of, for example, silicon oxide or silicon nitride. For example, a nitride layer for forming spacers is formed on an entire surface of the substrate 110 including the gate structure 140, and then, an etching process such as an etch-back is performed to form the spacers 152 on the side walls of the gate structure 140.

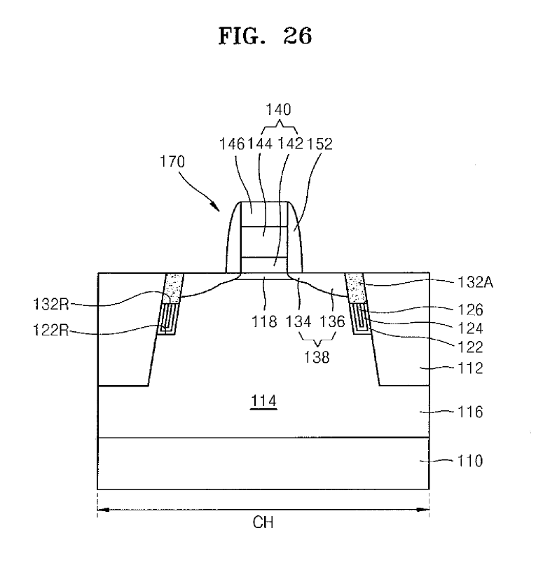

Referring to FIG. 26, high concentration impurity regions 136 are formed.

The high concentration impurity regions 136 correspond to the deep source/drain regions 136 formed in the active area 114. In addition, the high concentration impurity regions 136 may be, for example, p-type.

For example, p-type impurities, such as boron (B) is injected by using the gate structure 140 and the spacers 152 as an ion injection mask to form the p-type high concentration impurity regions 136 in the active area 114.

The source/drain regions 138 include, for example, the extended source/drain regions 134 formed in the active area 114, and the deep source/drain regions 136 aligned by the gate structure 140 and the spacers 152 to be formed in the active area 114.

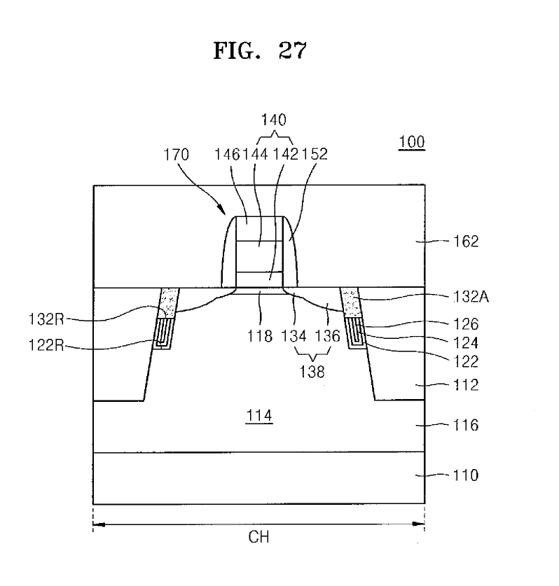

Referring to FIG. 27, an interlayer dielectric 162 covering the PMOS transistor 170 and the substrate 110 is formed.

Next, the plurality of source/drain contacts 164 (refer to FIG. 1) that penetrate through the interlayer dielectric 162 to be electrically connected to the source/drain regions 138 are formed.

Although processes of the method of manufacturing the semiconductor device 200 or 300 shown in FIG. 2 or FIG. 3 are not described herein, the manufacturing method would be readily understood by one of ordinary skill in the art in view of the method of manufacturing the semiconductor device 100 of FIG. 1 described above. Thus, descriptions about the manufacturing method are not provided here.

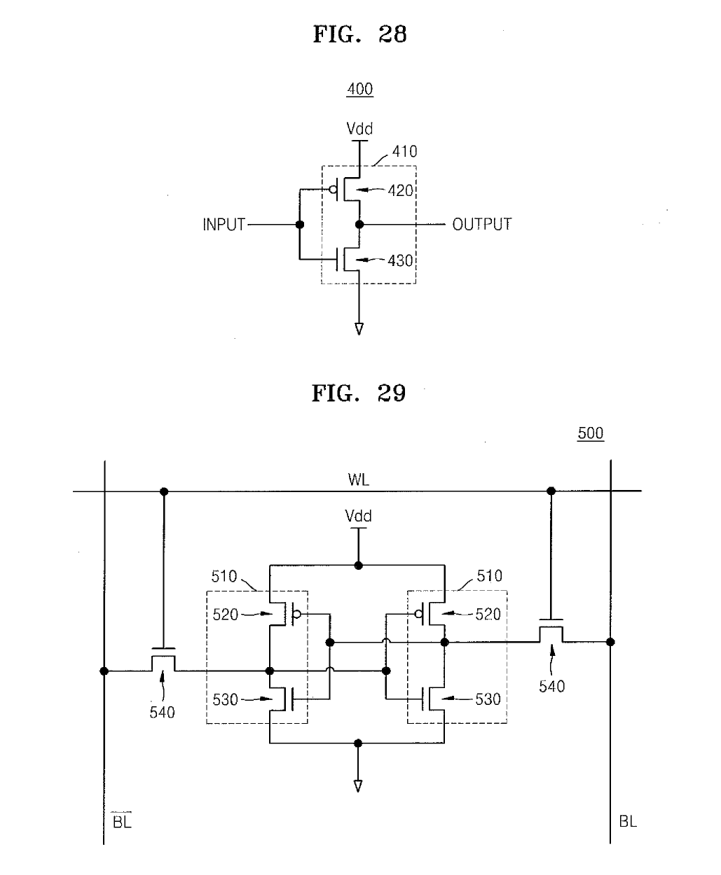

FIG. 28 is a circuit diagram of a CMOS inverter 400 that is a semiconductor device according to an embodiment of the present invention.

The CMOS inverter 400 includes, for example, a CMOS transistor 410. The CMOS transistor 410 includes, for example, a PMOS transistor 420 and an NMOS transistor 430 connected between a power source terminal Vdd and a ground terminal. The PMOS transistor 420 and the NMOS transistor 430 may be, for example, at least one of the semiconductor devices 100, 100a through 100d, 200, 200a through 200d, 300, 300a through 300d described with reference to FIGS. 1 through 3, respectively.

FIG. 29 is a circuit diagram of a CMOS SRAM device 500 that is an example of a semiconductor device according to an embodiment of the present invention.

The CMOS SRAM device 500 includes, for example, a pair of driving transistors 510. The pair of driving transistors 510 respectively include, for example, a PMOS transistor 520 and an NMOS transistor 530 connected between a power source terminal Vdd and a ground terminal. The CMOS SRAM device 500 further includes, for example, a pair of transfer transistors 540. A source of the transfer transistor 540 is cross-connected to a common node of the PMOS transistor 520 and the NMOS transistor 530 configuring the driving transistor 520. The power source terminal Vdd is connected to a source of the PMOS transistor 520, and the ground terminal is connected to a source of the NMOS transistor 530. Word lines WL are connected to gates of the pair of transfer transistors 540, and bit lines BL and inversed bit lines are respectively connected to drains of the pair of transfer transistors 540.

At least one of the driving transistor 510 and the transfer transistor 540 of the CMOS SRAM device 500 includes, for example, at least one of the semiconductor devices 100, 100a through 100d, 200, 200a through 200d, 300, 300a through 300d described with reference to FIGS. 1 through 3.

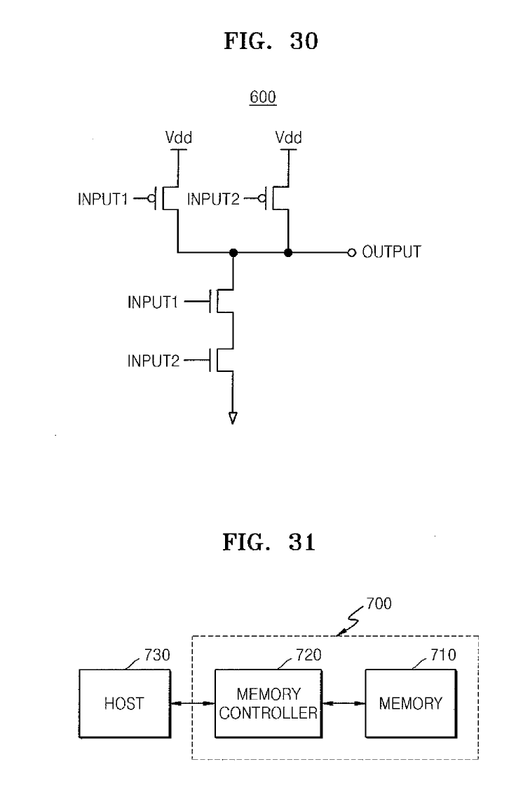

FIG. 30 is a circuit diagram of a CMOS NAND circuit 600 that is an example of a semiconductor device according to an embodiment of the present invention.

The CMOS NAND circuit 600 includes, for example, a pair of CMOS transistors to which input signals different from each other are transmitted. At least one transistor of the pair of CMOS transistors may include, for example, at least one of the semiconductor devices 100, 100a through 100d, 200, 200a through 200d, 300, 300a through 300d described with reference to FIGS. 1 through 3.

FIG. 31 is a block diagram of an electronic system 700 that is an example of a semiconductor device according to an embodiment of the present invention.

The electronic system 700 includes, for example, a memory 710 and a memory controller 720. The memory controller 720 controls the memory 710 in response to a request of a host 730 to read data from and/or to write data in the memory 710. At least one of the memory 710 and the memory controller 720 may include, for example, at least one of the semiconductor devices 100, 100a through 100d, 200, 200a through 200d, 300, 300a through 300d described with reference to FIGS. 1 through 3.

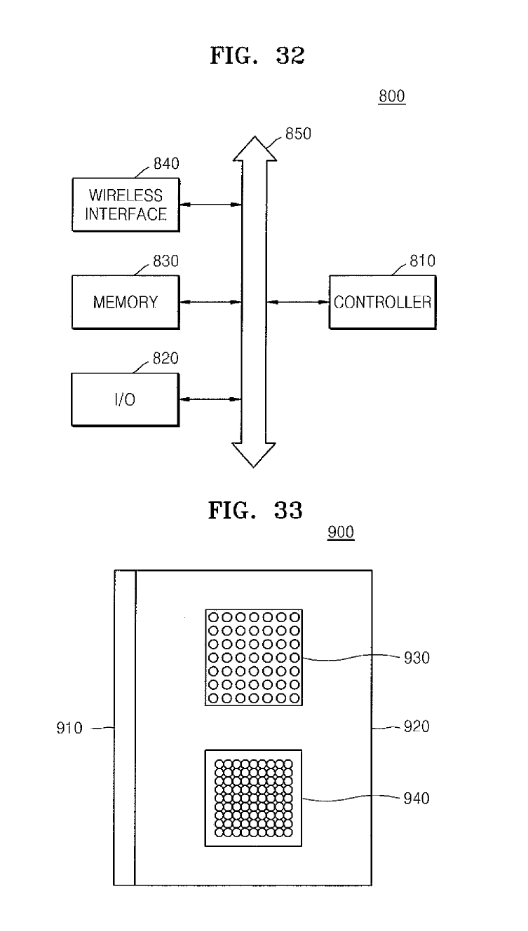

FIG. 32 is a block diagram of an electronic system 800 that is an example of a semiconductor device according to an embodiment of the present invention.

The electronic system 800 may configure a wireless communication apparatus, or an apparatus transmitting and/or receiving information under a wireless environment. The electronic system 800 includes, for example, a controller 810, an input/output device (I/O) 820, a memory 830, and a wireless interface 840, which are connected to each other via a bus 850.

The controller 810 may include, for example, at least one of a microprocessor, a digital signal processor, or other similar processing apparatuses. The I/O device 820 may include, for example, at last one of a keypad, a keyboard, and a display. The memory 830 may be used to store a command executed by the controller 810. For example, the memory 830 may store user data. The electronic system 800 may use the wireless interface 840 for transmitting/receiving data via a wireless communication network. The wireless interface 840 may include, for example, an antenna and/or a wireless transceiver. In the present embodiment of the present invention, the electronic system 800 may be used in a communication protocol system of a third-generation communication system, such as for example, a code division multiple access (CDMA), a global system for mobile communications (GSM), a north American digital cellular (NADC), an extended-time division multiple access (E-TDMA), and/or a wide band code division multiple access (WCDMA). The electronic system 800 includes, for example, at least one of the semiconductor devices 100, 100a through 100d, 200, 200a through 200d, 300, 300a through 300d described with reference to FIGS. 1 through 3.

FIG. 33 shows an electronic subsystem 900 that is an example of a semiconductor device according to an embodiment of the present invention.

The electronic subsystem 900 may be, for example, a modular memory device. The electronic subsystem 900 may include, for example, an electrical connector 910 and a printed circuit board 920. The printed circuit board 920 may support, for example, a memory unit 930 and a device interface unit 940. The memory unit 930 may have various data storage structures. The device interface unit 940 may be electrically connected to each of the memory unit 930 and the electrical connector 910 via, for example, the printed circuit board 920. The device interface unit 940 may include, for example, a voltage, a clock frequency, and a component necessary for generating a protocol logic. The electronic subsystem 900 may include, for example, at least one of the semiconductor devices 100, 100a through 100d, 200, 200a through 200d, 300, 300a through 300d described with reference to FIGS. 1 through 3.

Having described exemplary embodiments of the present invention, it is further noted that it is readily apparent to those of ordinary skill in the art that various modifications may be made without departing from the spirit and scope of the invention which is defined by the metes and bounds of the appended claims.

1. A semiconductor device comprising:
an active area defined by a device isolation layer and including a plurality of source/drain regions;
a gate structure disposed on the active area and extending in a first direction;
a stress layer contacting a side surface of each of the plurality of source/drain regions; and
a plurality of source/drain contacts disposed in the active area and connected to the plurality of source/drain regions.

2. The semiconductor device of claim 1, wherein the gate structure is a gate of a p-channel metal oxide semiconductor (PMOS) transistor, and the stress layer is a compressive stress layer.

3. The semiconductor device of claim 1, wherein the gate structure is a gate of an n-channel metal oxide semiconductor (NMOS) transistor, and the stress layer is a tensile stress layer.

4. The semiconductor device of claim 1, wherein the stress layer is disposed symmetrically on opposing sides the gate structure.

5. The semiconductor device of claim 1, wherein the stress layer overlaps with the active area, and is disposed on a partial region of the active area, which contacts a side surface of the device isolation layer.

6. The semiconductor device of claim 5, wherein the stress layer extends between the plurality of source/drain contacts and toward the gate structure in a second direction that is perpendicular to the first direction.

7. The semiconductor device of claim 1, wherein the stress layer overlaps with the device isolation layer, and is disposed on a partial region of the device isolation layer, which contacts a side surface of the active area.

8. The semiconductor device of claim 7, wherein the stress layer extends between the plurality of source/drain contacts and toward the gate structure in a second direction that is perpendicular to the first direction.

9. The semiconductor device of claim 1, wherein the stress layer overlaps with the active area and the device isolation layer, and is disposed on partial regions of the active area and the device isolation layer, which contact each other.

10. The semiconductor device of claim 9, wherein the stress layer extends between the plurality of source/drain contacts and toward the gate structure in a second direction that is perpendicular to the first direction.

11. The semiconductor device of claim 1, further comprising a plurality of recess regions disposed under the stress layer and an insulating layer disposed on a lower surface and side surfaces of the recess regions.

12. The semiconductor device of claim 11, wherein the insulating layer has a cup-shaped cross section.

13. A semiconductor device comprising:
a p-channel metal oxide semiconductor (PMOS) transistor comprising a plurality of source/drain regions disposed in an active area defined by a device isolation layer and a gate structure extending on the active area in a first direction;
a compressive stress layer extending in the first direction and contacting a side surface of each of the source/drain regions; and
a plurality of source/drain contacts disposed on the active area and connected to the source/drain regions,
wherein upper surfaces of the active area and the stress layer are located at a plane of a same level as each other.

14. The semiconductor device of claim 13, wherein the compressive stress layer contacts a side surface of the device isolation layer and a side surface of the active area.

15. The semiconductor device of claim 13, further comprising:
a plurality of recess regions disposed under the stress layer and an insulating layer disposed on a lower surface and side surfaces of the recess regions;
a barrier metal layer disposed on the insulating layer; and
a conductive layer disposed on the barrier metal layer.

16-20. (canceled)
